(19) United States
(12) Patent Application Publication
(10) Pub. No.: US 2014/0193018 A1
(43) Pub. Date: Jul. 10, 2014

(54) ELECTRONIC DEVICE HAVING SENSOR FOR DETECTING EXTERNAL ENVIRONMENT

(71) Applicant: Samsung Electronics Co., Ltd., Suwon-si (KR)

(72) Inventors: Ho-Yeong LIM, Gumi-si (KR); Joon HEO, Suwon-si (KR)

(73) Assignee: Samsung Electronics Co., Ltd., Suwon-si (KR)

(21) Appl. No.: 14/082,492

(22) Filed: Nov. 18, 2013

(30) Foreign Application Priority Data
Jan. 7, 2013 (KR) 10-2013-0001605

(51) Int. Cl. H04R 1/02; H05K 7/14

(52) U.S. Cl. CPC H04R 1/02; H05K 7/14
USPC 381/334; 381/91; 361/809

(57) ABSTRACT

An electronic device is provided. The electronic device includes a case frame having an opening, a first unit, and at least one external environment sensor. The opening has a predetermined size and is formed in the case frame. The first unit is disposed inside the electronic device and is configured to perform a first function via the opening. The at least one external environment sensor is disposed inside the electronic device and detects an external environment condition via the opening. The electronic device uses an already formed opening for data input/output as an external connection path for the external environment sensor to avoid creating a separate opening for the external environment sensor.

### CROSS-REFERENCE TO RELATED APPLICATION(S)

This application claims the benefit under 35 U.S.C. §119(a) of a Korean patent application filed on Jan. 7, 2013 in the Korean Intellectual Property Office and assigned Serial No. 10-2013-0001605, the entire disclosure of which is hereby incorporated by reference.

### TECHNICAL FIELD

The present disclosure relates to an electronic device including a sensor for detecting an external environment.

### BACKGROUND

Recently, electronic devices are applied to various fields closely related to our lives. Mobile terminals are becoming one of the more indispensable devices in our lives. Since the processing speed of the mobile terminal improves rapidly and smartphones including various additional functions such as web surfing are becoming mainstream, it is no exaggeration to say that one person possesses at least one mobile terminal

Electronic devices are brought to the market in various sizes depending on their functions and a user's preference. A lightweight electronic device with a slimmer profile is more preferred by a user even though the electronic device possesses generally the same functions as devices of other companies.

Since the electronic devices are becoming increasingly slim and multifunctional, various devices for meeting this trend are mounted. Particularly, electronic devices are incorporating a temperature sensor for detecting ambient temperature, humidity sensors for detecting ambient humidity in addition to the other functions of the electronic device to maximize additional use convenience of a user.

Although mounted inside the electronic device, these temperature sensor and humidity sensors should be mounted in an isolated manner so that they are not influenced by heat emitted from various electronic function groups mounted inside the electronic device, and should be disposed at a position exposed to an external environment.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide an electronic device having an external environment sensor not requiring a separate opening or a cutting line.

Another aspect of the present disclosure is to provide an electronic device having an external environment sensor, realized to exclude a separate opening or a cutting line to achieve an elegant appearance without limitation in design.

Another aspect of the present disclosure is to provide an electronic device having an external environment sensor, realized to contribute to slimness of the electronic device by using an opening for data input/output already formed in the electronic device.

In accordance with an aspect of the present disclosure, an electronic device is provided. The electronic device includes a case frame having an opening of a predetermined size formed therein, a first unit disposed inside the electronic device and configured to perform a first function via the opening, and a second unit disposed inside the electronic device and configured to perform a function different from the first function via the opening.

In accordance with an aspect of the present disclosure, the second unit may be an external environment sensor configured to detect an external environment condition of the electronic device.

In accordance with an aspect of the present disclosure, the external environment sensor may be at least one of a temperature sensor, a humidity sensor, an odorant sensor, and a gas sensor.

In accordance with an aspect of the present disclosure, the first unit may be a microphone unit disposed inside the electronic device, and the first function may be a function for collecting ambient sounds of the electronic device using the microphone unit via the opening.

In accordance with an aspect of the present disclosure, the first unit may be a speaker unit disposed inside the electronic device, and the first function may be a function for emitting a sound of the speaker unit via the opening.

In accordance with an aspect of the present disclosure, the first unit may be an ear jack disposed inside the electronic device, and the first function may a function for outputting communication and voice/sound by an ear microphone unit electrically connected via an opening that cooperates with an ear jack hole of the ear jack.

In accordance with an aspect of the present disclosure, the first unit may be a connector port disposed inside the electronic device to receive an external cable connector, and the first function may be a data transmission/reception function via the cable connector or a charging function.

In accordance with an aspect of the present disclosure, a partition wall for isolating the opening from a specific inner space of the electronic device, and simultaneously providing a sealed space for the second unit may be further installed or formed inside the case frame. This partition wall may provide the sealed space by contacting a mainboard of the electronic device when the case frame is assembled.

In accordance with an aspect of the present disclosure, a filtering unit for performing a ventilation function and preventing inflow of an external foreign substance may be further installed in the opening.

In accordance with an aspect of the present disclosure the filtering unit may comprise at least one of an air filter, a membrane filter, a non-woven fabric, a sponge may be installed.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view illustrating an electronic device having an external environment sensor according to an embodiment of the present disclosure;

FIG. 2 is a cross-sectional view illustrating a portion of an electronic device in which an external environment sensor has been installed according to an embodiment of the present disclosure;

FIG. 3 is a perspective view illustrating a portion of an electronic device in which an external environment sensor is installed according to an embodiment of the present disclosure; and

FIG. 4 is a cross-sectional view illustrating a portion of an electronic device in which an external environment sensor has been installed according to an embodiment of the present disclosure.

Throughout the drawings, like reference numerals will be understood to refer to like parts, components and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding, but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions are omitted for clarity and conciseness.

The terms and words used in the following description and claims are not limited to the bibliographical meanings, but are merely used by the inventor to enable a clear and consistent understanding of the present disclosure. Accordingly, it should be apparent to those skilled in the art that the following description of various embodiments of the present disclosure are provided for illustration purposes only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In describing the present disclosure, for an electronic device, a portable terminal for communication having a composite touchscreen unit is illustrated and described, but the present disclosure is not limited thereto. For example, the electronic device may be any of various devices having a composite touchscreen unit, such as a Personal Digital Assistant (PDA), a laptop computer, a smartphone, a netbook, a Mobile Internet Device (MID), an Ultra Mobile Personal Computer (UMPC), a tablet PC, a navigation device, an MP3 player, and the like.

Furthermore, the present disclosure is applicable to various devices mounting an external environment sensor to measure an ambient external environment condition as well as the electronic device. For example, the present disclosure is applicable to various devices whose appearance is formed using a case frame and having an opening connected to the inside of the device for other functions.

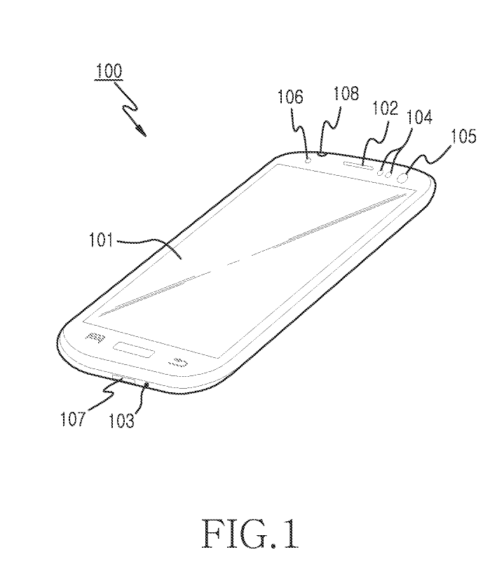

FIG. 1 is a perspective view illustrating an electronic device having an external environment sensor according to an embodiment of the present disclosure.

Referring to FIG. 1, the electronic device 100 includes a display unit 101 on a front side. A touchscreen unit that performs data input/output simultaneously may be used as the display unit 101. To transmit voice to a counterpart user, a microphone hole 103 for exposing a microphone unit is formed in the lower side of the display unit 101. To receive the counterpart user's voice, a plurality of speaker holes 102 for exposing a speaker unit (not shown) mounted inside the electronic device 100, for outputting a voice and/or sound, is formed in the upper side of the display unit 101.

A plurality of auxiliary elements 104, 105, and 106 for additional functions of the electronic device may be disposed in the neighborhood of the speaker holes 102. For example, when the electronic device 100 is a mobile terminal, these auxiliary elements may be a camera module 105 for shooting an object, an illumination sensor 104 for sensing the ambient brightness to control the brightness of the display unit 101, a proximity sensor 104 for turning off a display screen during communication, and a service LED 106 for allowing a user of the mobile terminal to visually recognize a transmission/reception state of a message, a call connection state, and the like.

To perform data input/output with the electronic device or to charge a battery pack inside the electronic device, a connector insert hole 107 included in a connector port socket disposed inside the electronic device, for connecting an external cable is formed in the lower side of the electronic device 100. A user of the electronic device may connect a connector of a data cable or a charge cable to the connector port socket 150 exposed via the connector insert hole 107 to transmit/receive data or perform a charging function.

A microphone hole 108 is formed in the upper side of the electronic device 100. A user may listen to multimedia content such as music, images, and the like using an external ear phone unit or an ear microphone unit. The user may also communicate with a counterpart user.

At least one external environment sensor (according to the present disclosure is mounted inside the electronic device 100. The external environment sensor 130 may use an existing opening as a connection path that may be exposed to the outside. For example, as described above, openings for external connection such as the microphone hole 103, the speaker hole 102, the connector insert hole 107, and the ear jack hole 108 may be used as the connection path.

According to the present disclosure, one or more sensors as the external environment sensors 130 may be disposed in one or more openings, or a plurality of sensors may be disposed in one opening. For the external environment sensors 130, various sensors for detecting an external environment may be used, such as a gas sensor, an odorant sensor, a temperature sensor, a humidity sensor, and the like.

These sensors 130 may be mounted on a mainboard (Printed Circuit Board (PCB)) of the electronic device 100, but they are not limited thereto and may be installed in various places such as the case frame inner side of the electronic device, and the like. The sensors 130 may be electrically connected with the mainboard via a session cable, a Flexible Printed Circuit (FPC), and the like.

A structure in which an external environment sensor is mounted in the electronic device according to the present disclosure is described below.

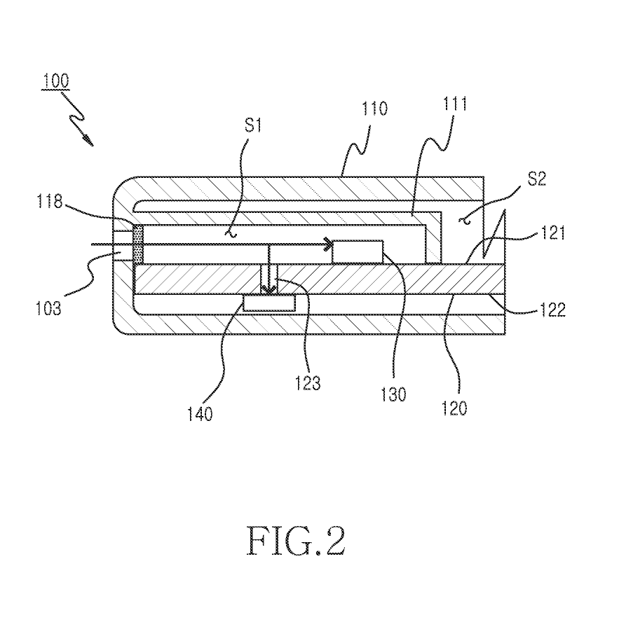

FIG. 2 is a cross-sectional view illustrating a portion of an electronic device in which an external environment sensor included in the electronic device has been installed according to an embodiment of the present disclosure.

Referring to FIG. 2, the microphone hole 103 is also used as the external connection path for the external environment sensor 130.

A mainboard 120 is mounted in the inner space S2 of a case frame 110 of the electronic device 100. For the mainboard 120, various known substrates may be applied, such as a hard type PCB or an FPC, and the like. A microphone unit 140 is mounted on a back side 122 of the mainboard 120, and the external environment sensor 130 according to the present disclosure is mounted on a front side 121 of the mainboard 120. A temperature sensor may be mounted as the external environment sensor 130.

The microphone hole 103 for receiving external voice and sound in the microphone unit 140 is formed in the case frame 110. To connect spaces between the microphone hole 103 and the microphone unit 140, a wave guide hole 123 passing through from the back side 122 on which the microphone unit 140 has been mounted to the front side 121 is formed in the mainboard 120. Accordingly, external voice, sound, and the like may be received via the microphone hole 103 of the electronic device 100 and introduced to the microphone unit 140 via the wave guide hole 123 of the mainboard 120.

For efficient collection of voices or sounds introduced to the microphone unit 140, a partition wall 111 is installed or formed above the mainboard 120 so that a wave guide space S1 is formed. The partition wall 111 may be disposed inside the electronic device 100 and configured to provide the wave guide space S1 completely isolated from the space S2 which is an installation space in which other parts of the electronic device 100 are installed. Accordingly, the partition wall 111 may be integrally formed while the case frame 110 of the electronic device 100 is injection-molded. The partition wall 111 may also be assembled such that the partition wall 111 is sealed when the case frame 110 and the mainboard 120 couple to each other. Accordingly, when the case frame 110 and the mainboard 120 are coupled to each other, the lower portion of the partition wall 111 naturally contacts the front side 121 of the mainboard 120, so that the wave guide space S1 may be formed.

The external environment sensor 130 may be mounted on the mainboard 120 and disposed inside the wave guide space S1. With this configuration, the external environment sensor 130 is completely isolated from the inner space S2 of the electronic device 100 by the partition wall 111, and simultaneously, disposed inside the space S1 having generally the same condition as an external environment via the microphone hole 103, so that the external environment sensor 130 may measure the external environment condition more accurately. A distorted environment different from the external environment due to various heat emitting devices mounted as parts inside the electronic device 100 may be mitigated by the partition wall 111. Accordingly, the space S1 formed by the partition wall 111 may be utilized as a space for efficient sound collection of the microphone unit 140, and simultaneously utilized as a space for accurate measurement of an external environment by the external environment sensor 130.

A filtering unit 118 is further installed in the microphone hole 103. The filtering unit 118 may be realized using various materials that may prevent introduction of an external foreign substance to the inside while allowing ventilation from the outside. The filtering unit 118 may be formed of various materials such as an air filter, a membrane filter, a non-woven fabric, a sponge, and the like.

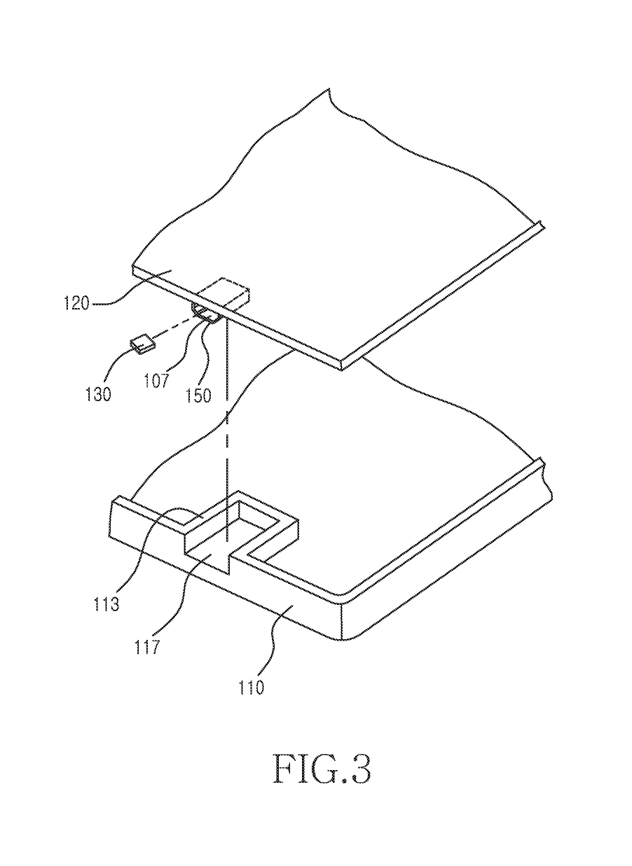

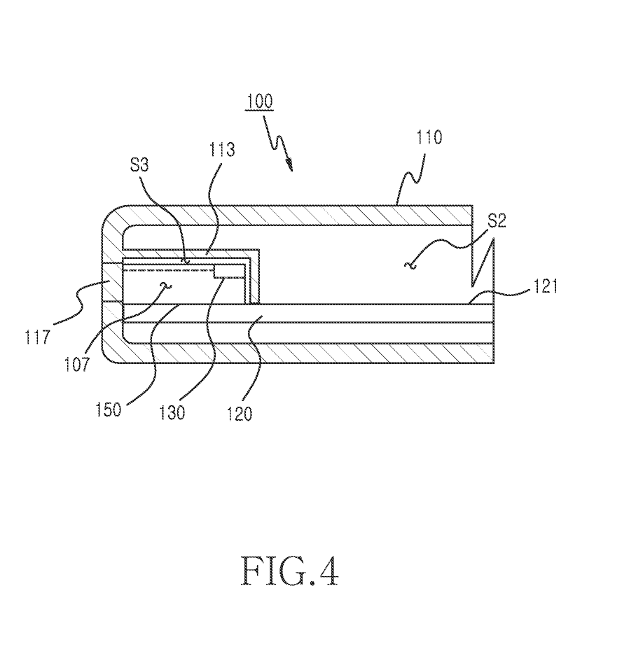

FIG. 3 is a perspective view illustrating a portion of an electronic device in which an external environment sensor is installed according to an embodiment of the present disclosure, and FIG. 4 is a cross-sectional view illustrating a portion of an electronic device in which an external environment sensor has been installed according to an embodiment of the present disclosure. FIG. 4 illustrates a state where the external environment sensor 130 has been applied to the connector insert hole 107 of FIG. 1.

While FIG. 2 illustrates the external environment sensor 130 and the microphone unit 140 are mounted on the different sides of the mainboard 120, FIG. 4 illustrates the external environment sensor 130 installed inside the connector port socket 150.

Referring to FIGS. 3 and 4, the connector port socket 150 is mounted on the mainboard 120. In this case, the connector port socket 150 may be mounted in a Surface Mounted Device (SMD) type. The external environment sensor 130 is mounted inside the connector insert hole 107 of the connector port socket 150.

Since the external environment sensor 130 is installed inside the connector port socket 150, the external environment sensor 130 is isolated from the inner space S2 of the electronic device 100, but a partition wall 113 may be also formed on the case frame 110 to prevent heat transference from the inner space S2 of the electronic device 100 due to an assembly error between the connector port socket 150 and the case frame 110 of the electronic device, an opening that may be formed in the lateral wall of the connector port socket 150, or the connector port socket 150 formed of metal. Also, a space S3 that may completely seal the connector port socket 150 may be formed when the case frame 110 and the mainboard 120 couple to each other. Accordingly, even when an assembly error between a socket receiving portion 117 and the connector port socket 150 occurs, the space S3 in which the external environment sensor 130 has been installed may be isolated from the inner space S2 of the electronic device 100 by the partition wall 113.

The external environment sensor 130 should be installed at a position so as not to interfere when a cable connector is inserted even though the external environment sensor 130 is installed in a socket receiving hole 107 of the connector port socket 150.

Although not shown, the external environment sensor 130 may be mounted on the mainboard 120 and mounted on the mainboard 120 inside the connector insert hole 107 of the connector port socket 150. In this case, the external environment sensor 130 may be installed outside the connector port socket 150 and disposed inside the space S3 which is the sealed space formed by the partition wall 113.

The electronic device according to various embodiments of the present disclosure uses an already formed opening for data input/output as an external connection path for an external environment sensor to exclude an opening that should be formed separately for sensing, so that the appearance of the electronic device becomes elegant and limitations in design are removed, which may contribute to slimness of the electronic device.

While the present disclosure has been shown and described with reference to various embodiments thereof, it will be understood by those skilled in the art that various changes in form and details may be made therein without departing from the spirit and scope of the present disclosure as defined by the appended claims and their equivalents.

For example, the above-described external environment sensor may be mounted in the inner space of the ear jack hole of FIG. 1. Also, when the microphone unit or the speaker unit and a vibrator are configured as one assembly in a box type carrier of a predetermined shape and applied to an electronic device, the external environment sensor may be additionally applied to the inner space of this carrier.

What is claimed is:

1. An electronic device comprising:
a case frame having an opening of a predetermined size formed therein;
a first unit disposed inside the electronic device and configured to perform a first function via the opening; and
a second unit disposed inside the electronic device and configured to perform a function different from the first function via the opening.

2. The electronic device of claim 1, wherein the second unit is an external environment sensor configured to detect an external environment condition of the electronic device.

3. The electronic device of claim 2, wherein the external environment sensor comprises at least one of a temperature sensor, a humidity sensor, an odorant sensor, and a gas sensor.

4. The electronic device of claim 1, wherein the first unit is a microphone unit disposed inside the electronic device, and
wherein the first function is a function for collecting ambient sounds of the electronic device using the microphone unit via the opening.

5. The electronic device of claim 1, wherein the first unit is a speaker unit disposed inside the electronic device, and
wherein the first function is a function for emitting a sound of the speaker unit via the opening.

6. The electronic device of claim 1, wherein the first unit is an ear jack disposed inside the electronic device, and
wherein the first function is a function for outputting communication and voice/sound by an ear microphone unit electrically connected via an opening that cooperates with an ear jack hole of the ear jack.

7. The electronic device of claim 6, wherein the second unit is installed inside the ear jack hole of the ear jack.

8. The electronic device of claim 1, wherein the first unit is a connector port disposed inside the electronic device to receive an external cable connector, and
wherein the first function is a data transmission/reception function or a charging function via the cable connector.

9. The electronic device of claim 8, wherein the second unit is installed inside a connector receiving hole of the connector port.

10. The electronic device of claim 1, wherein a partition wall for isolating the opening from a specific inner space of the electronic device, and simultaneously providing a sealed space for the second unit, is further installed or formed inside the case frame.

11. The electronic device of claim 10, wherein the partition wall is integrally formed with the case frame.

12. The electronic device of claim 10, wherein when the case frame is assembled, the partition wall contacts a mainboard of the electronic device to form the sealed space.

13. The electronic device of claim 4, wherein the partition wall is formed as a sealed space comprising the opening, and
wherein the sealed space is also used as a sound wave guide space via which external sounds are directed to only the microphone unit.

14. The electronic device of claim 10, wherein the partition wall is formed as a sealed space comprising the opening, and
wherein the sealed space is also used as a sound wave guide space via which external sounds are directed to only the microphone unit.

15. The electronic device of claim 5, wherein the partition wall is formed as a sealed space comprising the opening, and
wherein the sealed space is also used as a speaker sound wave guide space for emitting a speaker sound of the speaker unit.

16. The electronic device of claim 10, wherein the partition wall is formed as a sealed space comprising the opening, and
wherein the sealed space is also used as a speaker sound wave guide space for emitting a speaker sound of the speaker unit.

17. The electronic device of claim 1, further comprising a filtering unit installed in the opening and configured to perform a ventilation function and to prevent inflow of an external foreign substance.

18. The electronic device of claim 17, wherein the filtering unit comprises at least one of an air filter, a membrane filter, a non-woven fabric, and a sponge.

19. The electronic device of claim 1, wherein the electronic device is a mobile terminal for communication.

20. An electronic device comprising:
a case frame having an opening of a predetermined size formed therein;
a first unit disposed inside the electronic device and configured to perform a first function via the opening;
a second unit disposed inside the electronic device and configured to perform a function different from the first function via the opening; a partition wall for isolating the opening from a specific inner space of the electronic device, and simultaneously providing a sealed space for the second unit, is further installed or formed inside the case frame; and
a filtering unit installed in the opening and configured to perform a ventilation function and to prevent inflow of an external foreign substance.
